(19) United States
(12) Patent Application Publication
(10) Pub. No.: US 2015/0273659 A1
(43) Pub. Date: Oct. 1, 2015

(54) SUBSTRATE POLISHING APPARATUS

(71) Applicant: Ebara Corporation, Tokyo (JP)

(72) Inventors: Hiroshi Aono, Tokyo (JP); Tadakazu Sone, Tokyo (JP); Hideo Aizawa, Tokyo (JP); Kenji Shinkai, Tokyo (JP)

(21) Appl. No.: 14/641,623

(22) Filed: Mar. 9, 2015

(30) Foreign Application Priority Data
Mar. 31, 2014 (JP) 2014-074111

(51) Int. Cl. B24B 53/017; B08B 9/093; B24B 37/34; H01L 21/67

(52) U.S. Cl. CPC B24B 53/017; H01L 21/67011; B08B 9/093; B24B 37/34

(57) ABSTRACT

To provide a substrate polishing apparatus capable of effectively trapping a harmful substance suspended in a polishing chamber. The substrate polishing apparatus includes a polishing portion (303) that polishes a substrate in a polishing chamber (300), a gas supply port (301) that supplies gas into the polishing chamber (300), a gas discharge port (304) that discharges the gas from inside the polishing chamber (300), and a spray nozzle (302) that is provided on an inner wall surface of the polishing chamber (300) and sprays a cleaning liquid in a mist into the polishing chamber (300). The gas supply port (301) is arranged to generate a swirl flow.

### BACKGROUND OF THE INVENTION

1. Field of the Invention

The present invention relates to a substrate polishing apparatus that polishes a surface of a semiconductor substrate, and more particularly, to a substrate polishing apparatus appropriate for a case where a toxic substance is generated during polishing of the semiconductor substrate.

2. Description of the Related Art

Conventionally, a dangerous chemical liquid may be used in polishing of a compound semiconductor substrate (wafer). In a silicon carbide (SiC) substrate, for example, hydrogen fluoride (HF) may be used (see Japanese Patent Laid-Open No. 2008-166709). In a gallium arsenide (GaAs) substrate, harmful arsenic may be mixed with a polishing waste liquid.

In a conventional substrate polishing apparatus, a polishing atmosphere is locally isolated, and is evacuated by downflow, to prevent a harmful substance from leaking out. However, this apparatus does not clean the harmful substance, which has adhered to a polishing part, nor does it moisturize and trap the harmful substance suspended in the polishing atmosphere. Therefore, a cleaning apparatus, which cleans a polishing part and traps a suspended substance in a polishing atmosphere, is proposed (see Japanese Patent Laid-Open No. 2008-296293). In this conventional cleaning apparatus, a nozzle is installed in a polishing chamber, and a cleaning liquid is sprayed from the nozzle, to clean an inner wall surface and a ceiling surface of the polishing chamber.

However, a conventional cleaning apparatus aims at cleaning an inner wall surface and a ceiling surface of a polishing chamber, and is not intended to trap a harmful substance suspended in a space within the polishing chamber.

### SUMMARY OF THE INVENTION

The present invention has been made in view of the above described subject, and is directed to providing a substrate polishing apparatus capable of effectively trapping a harmful substance suspended in a polishing chamber.

According to an aspect of the present invention, a substrate polishing apparatus includes a polishing portion that polishes a substrate in a polishing chamber, a gas supply port that supplies gas into the polishing chamber, a gas discharge port that discharges the gas from inside the polishing chamber, and a spray nozzle that is provided on an inner wall surface of the polishing chamber and sprays a cleaning liquid in a mist into the polishing chamber, in which the gas supply port is arranged to generate a swirl flow.

Another aspect exists in the present invention, as described below. Therefore, the disclosure of the present invention is intended to provide an embodiment of a part of the present invention, and is not intended to limit the scope of the present invention herein described and claimed.

### BRIEF DESCRIPTION OF THE DRAWINGS

FIG. 1 is a plan view illustrating an overall configuration of a substrate processing apparatus to which a substrate polishing apparatus according to an embodiment of the present invention is applied;

FIG. 2 is a perspective view schematically illustrating a first polishing unit;

FIG. 3 is a cross-sectional view schematically illustrating a structure of a top ring;

FIG. 4 is a cross-sectional view schematically illustrating an example of another structure of the top ring;

FIG. 5 is a cross-sectional view for illustrating a mechanism for rotating and swinging the top ring;

FIG. 6 is a cross-sectional view schematically illustrating an internal structure of a polishing table;

FIG. 7 is a schematic view illustrating a polishing table including an optical sensor;

FIG. 8 is a schematic view illustrating a polishing table including a microwave sensor;

FIG. 9 is a perspective view illustrating a dresser;

FIG. 10 is a plan view illustrating a movement locus when the dresser dresses a polishing surface of a polishing pad;

FIG. 11A is a perspective view illustrating an atomizer, and FIG. 11B is a schematic view illustrating the bottom of an arm;

FIG. 12A is a side view illustrating an internal structure of the atomizer, and FIG. 12B is a plan view illustrating the atomizer;

FIG. 13A is a perspective view illustrating a polishing liquid supply nozzle, and FIG. 13B is an enlarged schematic view of a leading end of the polishing liquid supply nozzle as viewed from below;

FIG. 14 is a schematic view illustrating pure water supply piping in a polishing section;

FIG. 15 illustrates a substrate polishing apparatus according to an embodiment of the present invention;

FIG. 16 illustrates another example (a modified example 1) of the substrate polishing apparatus;

FIG. 17 illustrates another example (a modified example 2) of the substrate polishing apparatus;

FIG. 18 illustrates another example (a modified example 3) of the substrate polishing apparatus;

FIG. 19 illustrates a direction of a spray nozzle in the embodiment of the present invention;

FIG. 20 illustrates another example of a direction of the spray nozzle;

FIG. 21 is a plan view of the substrate polishing apparatus according to the embodiment of the present invention;

FIG. 22 illustrates a hand-held cleaning tool in the embodiment of the present invention;

FIG. 23 illustrates a sealed glove in the embodiment of the present invention; and

FIG. 24 illustrates a fixing member in the sealed type glove in the embodiment of the present invention.

### DETAILED DESCRIPTION OF THE PREFERRED EMBODIMENTS

A detailed description of the present invention will be described below. The following detailed description and accompanying drawings do not limit the present invention.

The substrate polishing apparatus according to the present invention is a substrate polishing apparatus including a polishing portion that polishes a substrate in a polishing chamber, a gas supply port that supplies gas (for example, air) to the polishing chamber, a gas discharge port that discharges the gas (for example, air including harmful materials) from inside the polishing chamber, and a spray nozzle that is provided on an inner wall surface of the polishing chamber and sprays a cleaning liquid in a mist into the polishing chamber, in which the gas supply port is arranged at a position offset sideward from the center of the inner wall surface of the polishing chamber, and a direction of the spray nozzle is set to spray the cleaning liquid toward a space at the center of the polishing chamber from the inner wall surface thereof.

By this configuration, when the gas is supplied from the gas supply port at the offset position on the inner wall surface of the polishing chamber, the gas swirls in the polishing chamber. When the cleaning liquid is sprayed from the spray nozzle toward the space at the center of the polishing chamber, the mist of cleaning liquid swirls in the gas in the polishing chamber. Even when a harmful substance (powder or gas) is generated in the polishing chamber during polishing of the substrate, therefore, the harmful substance can be trapped with the cleaning liquid. The harmful substance trapped with the cleaning liquid, together with the gas, is discharged from the gas discharge port. Thus, the harmful substance suspended in the polishing chamber can be effectively trapped and safely discharged.

In the substrate polishing apparatus according to the present invention, a plurality of gas supply ports may be respectively provided at different positions in an upper part of the polishing chamber.

By this configuration, the gas is supplied from the plurality of gas supply ports provided at the different positions in an upper part of the polishing chamber. Thus, the gas can easily swirls in the polishing chamber.

In the substrate polishing apparatus according to the present invention, the gas supply port may be provided in an upper part of the polishing chamber, and the spray nozzle may be arranged in the vicinity of the gas supply port.

By this configuration, the cleaning liquid can be put on the gas as soon as the gas is supplied from the gas supply port in an upper part of the polishing chamber. Thus, the harmful substance in the polishing chamber can be trapped from an early stage.

In the substrate polishing apparatus according to the present invention, the gas discharge port may be provided in the vicinity of the polishing portion in a lower part of the polishing chamber, and the spray nozzle may be arranged in the vicinity of the gas discharge port.

By this configuration, when the harmful substance (power or gas) is generated during polishing of the substrate in a lower part of the polishing chamber, the harmful substance can be trapped close to a place where the harmful substance has been generated (as soon as the harmful substance has been generated).

In the substrate polishing apparatus according to the present invention, the direction of the spray nozzle may be set in a direction opposite to the flow of the gas supplied from the gas supply port.

By this configuration, when the harmful substance flows on the gas in the polishing chamber, the cleaning liquid is sprayed toward the gas (harmful substance). Therefore, the harmful substance, which has flowed on the gas, can be effectively trapped with the cleaning liquid.

In the substrate polishing apparatus according to the present invention, the direction of the spray nozzle may be set in the same direction as that of the flow of the gas supplied from the gas supply port.

By this configuration, the cleaning liquid is sprayed in the same direction as that of the gas flowing in the polishing chamber. Therefore, the harmful substance in a wide range of the polishing chamber can be effectively trapped with the cleaning liquid on the gas flowing in the polishing chamber.

The substrate polishing apparatus according to the present invention may include a hand-held cleaning tool for cleaning the inside of the polishing chamber, and a sealed glove for operating the hand-held cleaning tool from outside the polishing chamber.

By this configuration, when the harmful substance is insufficiently removed only by being trapped with the cleaning liquid, the harmful substance remaining in the polishing chamber can be cleaned by operating the hand-held cleaning tool via the sealed glove.

The substance polishing apparatus according to the present invention may include a fixing member for fixing the sealed glove to the inner wall surface of the polishing chamber.

By this configuration, only when the sealed glove is not used, the sealed glove can be fixed to the inner wall surface of the polishing chamber using the fixing member, and the sealed glove can be prevented from contacting another structure in the polishing chamber.

According to the present invention, the harmful substance suspended in the polishing chamber can be effectively trapped.

### Embodiment

An embodiment of a substrate polishing apparatus according to the present invention will be described in detail below with reference to the drawings. Identical or corresponding components are assigned the same reference numerals, and detailed description thereof is omitted.

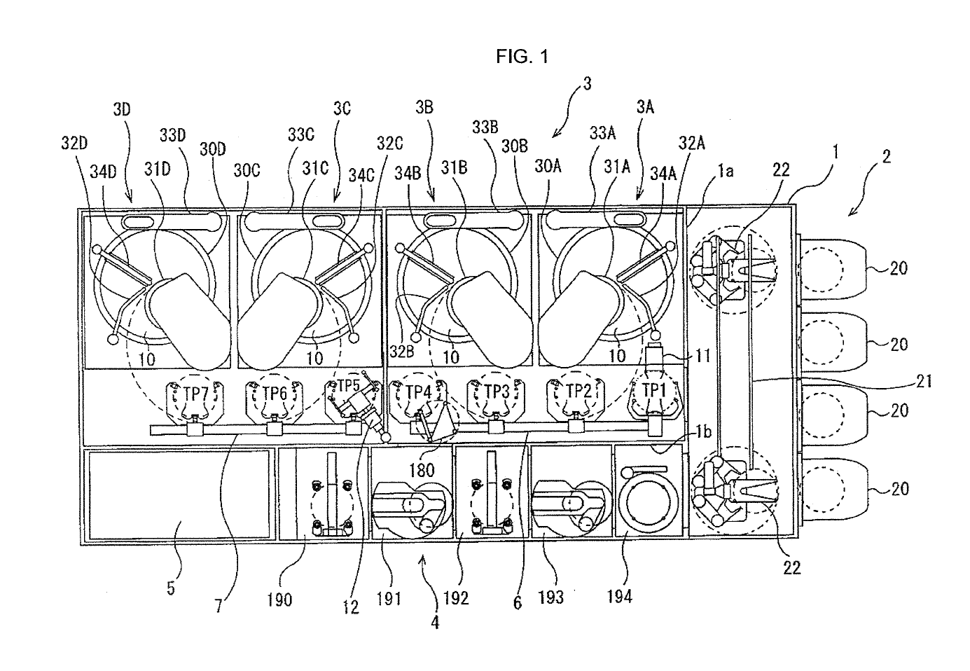

FIG. 1 is a plan view illustrating an overall structure of a substrate processing apparatus to which a substrate polishing apparatus according to an embodiment of the present invention is applied. As illustrated in FIG. 1, the substrate processing apparatus includes a substantially rectangular housing 1. The inside of the housing 1 is divided into a load/unload section 2, a polishing section 3, and a cleaning section 4 by bulkheads 1a and 1b. The load/unload section 2, the polishing section 3, and the cleaning section 4 are respectively independently assembled, and are independently evacuated. The substrate processing apparatus includes a control section 5 that controls the substrate processing operation.

The polishing section 3 is a region where a wafer is polished (flattened), and includes a first polishing unit 3A, a second polishing unit 3B, a third polishing unit 3C, and a fourth polishing unit 3D. The first polishing unit 3A, the second polishing unit 3B, the third polishing unit 3C, and the fourth polishing unit 3D are arranged in a longitudinal direction of the substrate processing apparatus, as illustrated in FIG. 1.

As illustrated in FIG. 1, the first polishing unit 3A includes a polishing table 30A to which a polishing pad 10 having a polishing surface is attached, a top ring 31A for retaining the wafer and polishing the wafer while pressing the wafer against the polishing pad 10 on the polishing table 30A, a polishing liquid supply nozzle 32A for supplying a polishing liquid or a dressing liquid (e.g., pure water) to the polishing pad 10, a dresser 33A for dressing a polishing surface of the polishing pad 10, and an atomizer 34A that atomizes a mixed fluid of the liquid (e.g., pure water) and gas (e.g., nitrogen gas) or a liquid (e.g., pure water) and sprays the mixed fluid or the liquid in a mist onto the polishing surface.

Similarly, the second polishing unit 3B includes a polishing table 30B to which a polishing pad 10 is attached, a top ring 31B, a polishing liquid supply nozzle 32B, a dresser 33B, and an atomizer 34B. The third polishing unit 3C includes a polishing table 30C to which a polishing pad 10 is attached, a top ring 31C, a polishing liquid supply nozzle 32C, a dresser 33C, and an atomizer 34C. The fourth polishing unit 3D includes a polishing table 30D to which the polishing pad 10 is attached, a top ring 31D, a polishing liquid supply nozzle 32D, a dresser 33D, and an atomizer 34D.

The first polishing unit 3A, the second polishing unit 3B, the third polishing unit 3C, and the fourth polishing unit 3D have the same structure, and thus the first polishing unit 3A will be described below.

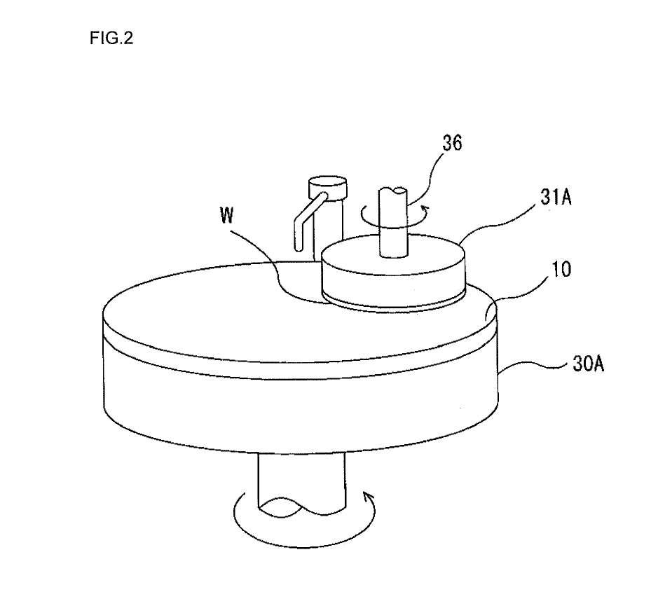

FIG. 2 is a perspective view schematically illustrating the first polishing unit 3A. The top ring 31A is supported on a top ring shaft 36. A polishing pad 10 is affixed to an upper surface of the polishing table 30A. An upper surface of the polishing pad 10 constitutes a polishing surface for polishing a wafer W. The polishing pad 10 can be replaced with a fixed abrasive grain. The top ring 31A and the polishing table 30A are configured to respectively rotate around their shaft centers, as indicated by arrows. The wafer W is retained on a lower surface of the top ring 31A by vacuum contact. During polishing, a polishing liquid is supplied to the polishing surface of the polishing pad 10 from the polishing liquid supply nozzle 32A, and the wafer W to be polished is pressed against the polishing surface and polished by the top ring 31A.

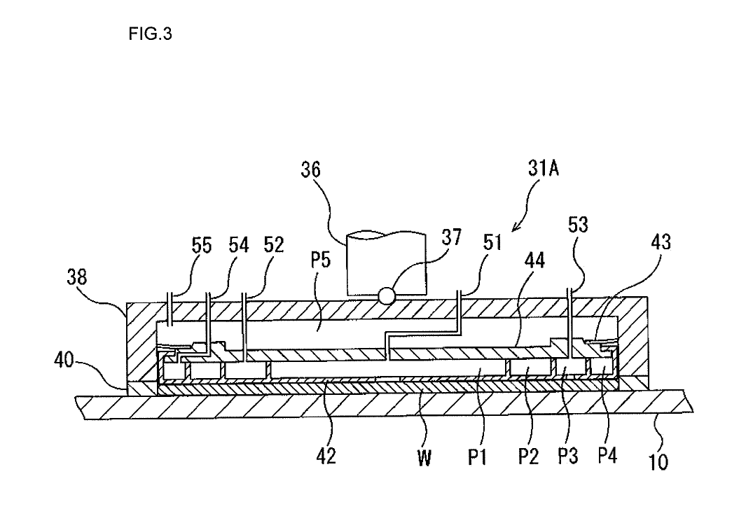

FIG. 3 is a cross-sectional view schematically illustrating a structure of the top ring 31A. The top ring 31A is connected to a lower end of the top ring shaft 36 via a universal joint 37. The universal joint 37 is a ball joint that transmits rotation of the top ring shaft 36 to the top ring 31A while allowing relative tilting between the top ring 31A and the top ring shaft 36. The top ring 31A includes a top ring main body 38 in a substantially circular disk shape and a retainer ring 40 arranged on the bottom of the top ring main body 38. The top ring main body 38 is formed of a material high in strength and rigidity such as a metal or ceramics. The retainer ring 40 is formed of a rigid resin material or ceramics. The retainer ring 40 may be formed integrally with the top ring main body 38.

A circular elastic pad 42 that abuts on the wafer W, an annular pressure sheet 43 composed of an elastic film, and a schematically disk-shaped chucking plate 44 that retains the elastic pad 42 are accommodated in a space formed inside the top ring main body 38 and the retainer ring 40. An upper peripheral end of the elastic pad 42 is retained in the chucking plate 44, and four pressure chambers (air bags) P1, P2, P3, and P4 are provided between the elastic pad 42 and the chucking plate 44. The pressure chambers P1, P2, P3, and P4 are formed of the elastic pad 42 and the chucking plate 44. A pressurized fluid such as pressurized air is supplied to the pressure chambers P1, P2, P3, and P4, respectively, via fluid paths 51, 52, 53, and 54, or is evacuated. The pressure chamber P1 at the center is circular, and the other pressure chambers P2, P3, and P4 are annular. The pressure chambers P1, P2, P3, and P4 are concentrically arranged.

Internal pressures of the pressure chambers P1, P2, P3, and P4 can be changed independently of one another by a pressure adjustment unit, described below. Thus, respective pressing forces against four regions, i.e., a central part, an inner intermediate part, an outer intermediate part, and a peripheral edge of the wafer W can be independently adjusted. The entire top ring 31A is raised and lowered so that the retainer ring 40 can be pressed against the polishing pad 10 with a predetermined pressing force. A pressure chamber P5 is formed between the chucking plate 44 and the top ring main body 38 so that the pressurized fluid is supplied to the pressure chamber P5 via a fluid path 55 or is evacuated. Thus, the whole of the chucking plate 44 and the elastic pad 42 can move up and down.

The peripheral edge of the wafer W is surrounded by the retainer ring 40 so that the wafer W does not project from the top ring 31A during polishing. An opening (not illustrated) is formed in a site of the elastic pad 42, which constitutes the pressure chamber P3, and a vacuum is formed in the pressure chamber P3 so that the wafer W can be adsorbed to and retained in the top ring 31A. Nitrogen gas, dried air, and compressed air are supplied to the pressure chamber P3 so that the wafer W is released from the top ring 31A.

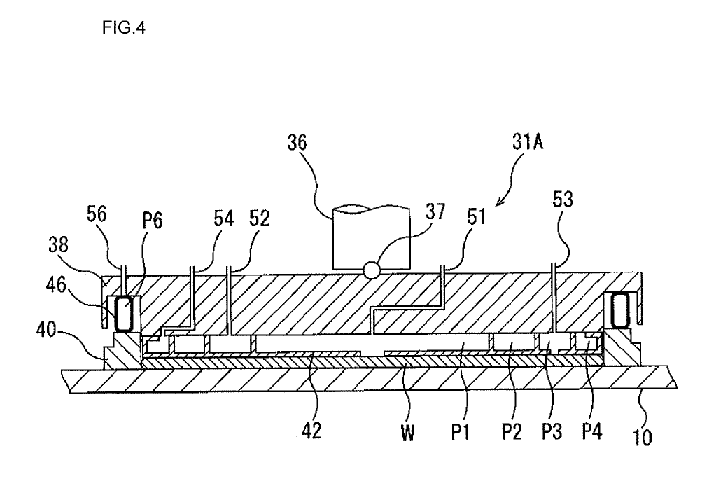

FIG. 4 is a cross-sectional view schematically illustrating an example of another structure of the top ring 31A. In this example, the chucking plate is not provided, and the elastic pad 42 is attached to a lower surface of the top ring main body 38. The pressure chamber P5 between the chucking plate and the top ring main body 38 is not provided, either. Instead, an elastic bag 46 is arranged between the retainer ring 40 and the top ring main body 38, and a pressure chamber P6 is formed inside the elastic bag 46. The retainer ring 40 is movable up and down relative to the top ring main body 38. A flow path 56 communicates with the pressure chamber P6 so that a pressurized fluid such as pressurized air is supplied to the pressure chamber P6 via the fluid path 56. An internal pressure of the pressure chamber P6 is adjustable by a pressure adjustment unit, described below. Therefore, a pressing force of the retainer ring 40 against the polishing pad 10 can be adjusted independently of a pressing force against the wafer W. Other structures and operations are the same as those of the top ring illustrated in FIG. 3. In the present embodiment, a top ring of any of the types illustrated in FIG. 3 or 4 can be used.

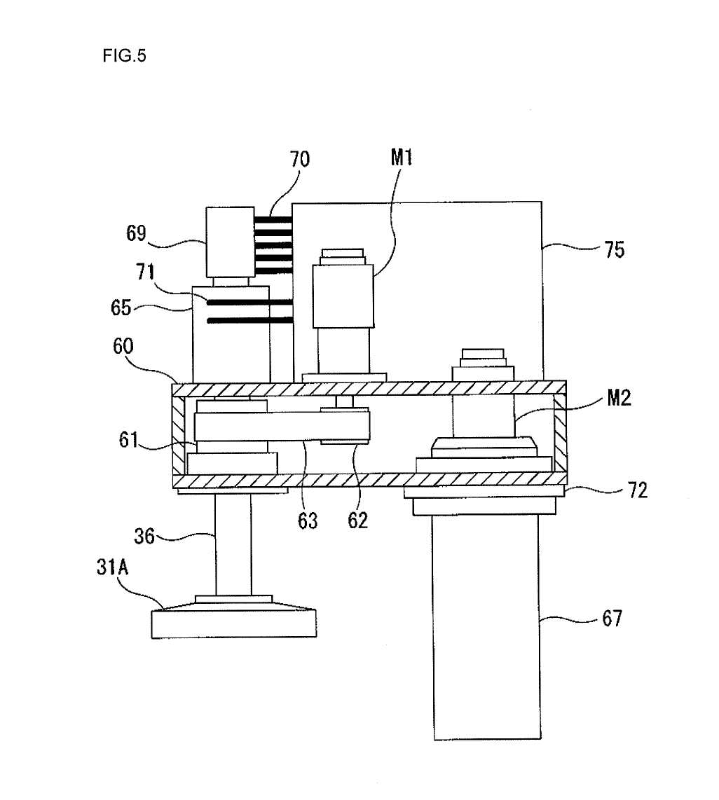

FIG. 5 is a cross-sectional view for illustrating a mechanism for rotating and swinging the top ring 31A. A top ring shaft (e.g., a spline shaft) 36 is rotatably supported on a top ring head 60. The top ring shaft 36 is connected to a rotation axis of a motor M1 via pulleys 61 and 62 and a belt 63, and the top ring shaft 36 and the top ring 31A rotate around their respective axes with the motor M1. The motor M1 is attached to the top of the top ring head 60. An air cylinder 65 serving as a vertical driving source connects the top ring head 60 and the top ring shaft 36. The top ring shaft 36 and the top ring 31A integrally move up and down with air (compressed gas) supplied to the air cylinder 65. The air cylinder 65 may be replaced with a mechanism having a ball screw and a servo motor as the vertical driving source.

The top ring head 60 is rotatably supported on a support shaft 67 via a bearing 72. The support shaft 67 is a fixed shaft, and does not rotate. A motor M2 is installed in the top ring head 60, and a relative position between the top ring head 60 and the motor M2 is fixed. A rotation axis of the motor M2 is connected to the support shaft 67 via a rotation transmission mechanism (e.g., a gear) (not illustrated). The motor M2 rotates so that the top ring head 60 swings around the support shaft 67. Therefore, the top ring 31A supported on a leading end of the top ring head 60 moves between an upper polishing position of the polishing table 30A and a side conveyance position of the polishing table 30A by swing motion of the top ring head 60. In the present embodiment, a swing mechanism for swinging the top ring 31A includes the motor M2.

In the top ring shaft 36, a through hole (not illustrated) extending in its longitudinal direction is formed. The flow paths 51, 52, 53, 54, 55, and 56 in the top ring 31A are connected to a rotation coupling 69 provided at an upper end of the top ring shaft 36 via the through hole. A fluid such as pressurized gas (clean air) or nitrogen gas is supplied to the top ring 31A via the rotation coupling 69, and the top ring 31A is evacuated. A plurality of fluid pipes 70 communicating with the fluid paths 51, 52, 53, 54, 55, and 56 (see FIGS. 3 and 4) is connected to the rotation coupling 69, and the fluid pipes 70 are connected to a pressure adjustment portion 75. A fluid pipe 71, which supplies pressurized air to the air cylinder 65, is also connected to the pressure adjustment portion 75.

The pressure adjustment portion 75 includes an electropneumatic regulator that regulates a pressure of a fluid supplied to the top ring 31A, piping respectively connected to the fluid pipes 70 and 71, air operate valves provided in the piping, an electropneumatic regulator that regulates a pressure of air serving as an operation source of the air operate valves, and an ejector that forms a vacuum in the top ring 31A, and are gathered together to constitute one block (unit). The pressure adjustment portion 75 is fixed to the top of the top ring head 60. The electropneumatic regulator in the pressure adjustment portion 75 adjusts respective pressures of pressurized gas supplied to the pressure chambers P1, P2, P3, P4, and P5 (see FIG. 3) in the top ring 31A and pressurized air supplied to the air cylinder 65. Similarly, the ejector in the pressure adjustment portion 75 forms a vacuum in the pressure chambers P1, P2, P3, and P4 in the top ring 31A and the pressure chamber P5 between the chucking plate 44 and the top ring main body 38.

Thus, the electropneumatic regulators and the valves serving as pressure adjustment equipment are installed close to the top ring 31A. Thus, controllability of the pressure within the top ring 31A is improved. More specifically, respective distances between the electropneumatic regulators and the pressure chambers P1, P2, P3, P4, and P5 are short. Thus, responsiveness to a pressure change instruction from the control section 5 is improved. Similarly, the ejector serving as a vacuum source is also installed close to the top ring 31A. Thus, responsiveness is improved when a vacuum is formed in the top ring 31A. A reverse surface of the pressure adjustment portion 75 can be used as a pedestal for mounting electric equipment. The necessity of a mounting frame, which has been conventionally required, can be eliminated.

The top ring head 60, the top ring 31A, the pressure adjustment portion 75, the top ring shaft 36, the motor M1, the motor M2, and the air cylinder 65 are configured as one module (hereinafter referred to as a top ring assembly). More specifically, the top ring shaft 36, the motor M1, the motor M2, the pressure adjustment portion 75, and the air cylinder 65 are mounted on the top ring head 60. The top ring head 60 is detachable from the support shaft 67. Therefore, the top ring head 60 and the support shaft 67 are separated from each other so that the top ring assembly can be detached from the substrate processing apparatus. Such a configuration enables maintenance properties of the support shaft 67 and the top ring head 60 to be improved. When an abnormal sound is generated from the bearing 72, for example, the bearing 72 can be easily replaced. When the motor M2 and a rotation transmission mechanism (speed reducer) are replaced, adjacent equipment needs not to be detached.

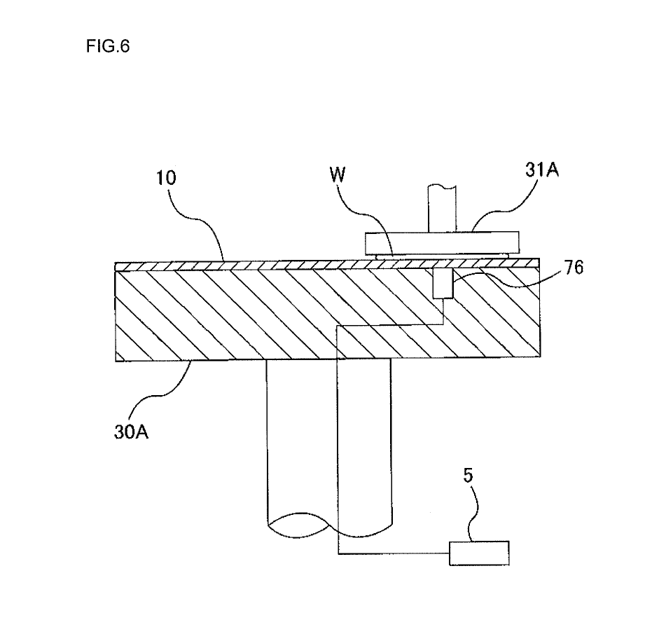

FIG. 6 is a cross-sectional view schematically illustrating an internal structure of the polishing table 30A. As illustrated in FIG. 6, a sensor 76, which detects a state of a film of the wafer W, is embedded inside the polishing table 30A. In this example, an eddy current sensor is used as the sensor 76. A signal of the sensor 76 is transmitted to the control section 5. The control section 5 generates a monitoring signal representing a film thickness. A value of the monitoring signal (and a sensor signal) does not represent the film thickness itself. However, a value of the monitoring signal changes depending on the film thickness. Therefore, the monitoring signal can be a signal representing the film thickness of the wafer W.

The control section 5 determines respective internal pressures of the pressure chambers P1, P2, P3, and P4 based on the monitoring signal, and issues an instruction to the pressure adjustment portion 75 so that the determined internal pressures are respectively formed in the pressure chambers P1, P2, P3, and P4. The control section 5 functions as a pressure control portion that operates the internal pressures of the pressure chambers P1, P2, P3, and P4 based on the monitoring signal, and an end point detector that detects a polishing end point.

The sensor 76 is also provided in the polishing table in each of the second polishing unit 3B, the third polishing unit 3C, and the fourth polishing unit 3D, like in the first polishing unit 3A. The control section 5 generates a monitoring signal from a signal fed from the sensor 76 of each of the polishing units 3A to 3D, and monitors the progress of polishing of the wafer W in each of the polishing units 3A to 3D. If the polishing units 3A to 3D polish a plurality of wafers, the control section 5 monitors respective monitoring signals representing the thicknesses of the wafers and controls respective pressing forces of the top rings 31A to 31D so that polishing times in the polishing units 3A to 3D are substantially the same based on the monitoring signals. Thus, the pressing forces of the top rings 31A to 31D during the polishing are thus respectively adjusted based on the monitoring signals so that the polishing times of the polishing units 3A to 3D can be leveled.

The wafer W may be polished by any one of the first polishing unit 3A, the second polishing unit 3B, the third polishing unit 3C, and the fourth polishing unit 3D, or may be continuously polished by the plurality of polishing units previously selected among the polishing units 3A to 3D. For example, the first polishing unit 3A and the second polishing unit 3B may polish the wafer W in this order. Alternatively, the third polishing unit 3C and the fourth polishing unit 3D may polish the wafer W in this order. Further, the first polishing unit 3A, the second polishing unit 3B, the third polishing unit 3C, and the fourth polishing unit 3D may polish the wafer W in this order. In either case, the polishing times in all the polishing units 3A to 3D are leveled so that throughput can be improved.

The eddy current sensor is appropriately used when the film of the wafer is a metallic film. If the film of the wafer is a film having light permeability such as an oxide film, an optical sensor can be used as the sensor 76. Alternatively, a microwave sensor may be used as the sensor 76. The microwave sensor can be used regardless of whether the film of the wafer is a metallic film or a nonmetallic film. An example of the optical sensor and the microwave sensor will be described below.

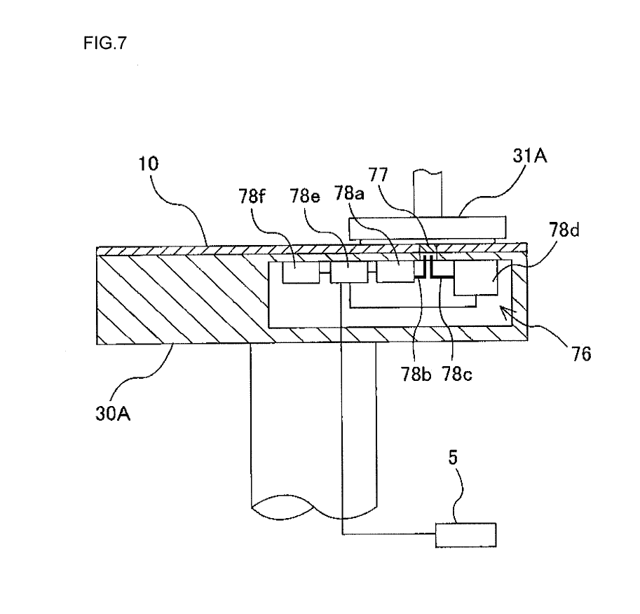

FIG. 7 is a schematic view illustrating a polishing table including an optical sensor. As illustrated in FIG. 7, an optical sensor 76, which detects a state of the film of the wafer W, is embedded in the polishing table 30A. The sensor 76 irradiates the wafer W with light, and detects a state (film thickness, etc.) of the film of the wafer W from an intensity (reflection intensity or reflectivity) of reflected light from the wafer W.

A light transmission portion 77 for transmitting the light from the sensor 76 is attached to the polishing pad 10. The light transmission portion 77 is formed of a material having a high transmission factor, and is formed of non-foamed polyurethane, for example. Alternatively, the light transmission portion 77 may be formed by providing the polishing pad 10 with a through hole and causing a transparent liquid to flow from below while the wafer W closes the through hole. The light transmission portion 77 is arranged at a position where it passes through the center of the wafer W retained in the top ring 31A.

The sensor 76 includes a light source 78a, a light emission optical fiber 78b serving as a light emitter that irradiates a polishing surface of the wafer W with light from the light source 78a, a light receiving optical fiber 78c serving as a light receiver that receives light reflected from the polishing surface, a spectroscope unit 78d including a spectroscope that disperses the light received by the light receiving optical fiber 78b and a plurality of light receiving elements that stores the light dispersed by the spectroscope as electrical information, an operation control portion 78e that controls lighting and extinction of the light source 78a and a timing of the start of reading of the light receiving elements within the spectroscope unit 78d, and a power source 78f that supplies power to the operation control portion 78e. Power is supplied to the light source 78a and the spectroscope unit 78d via the operation control portion 78e.

A light emission end of the light emission optical fiber 78b and a light receiving end of the light receiving optical fiber 78c are substantially perpendicular to the polishing surface of the wafer W. A photodiode array of 128 elements, for example, can be used as the light receiving elements in the spectroscope unit 78d. The spectroscope unit 78d is connected to the operation control portion 78e. Information from the light receiving element in the spectroscope unit 78d is fed to the operation control portion 78e, and spectrum data of the reflected light is generated based on the information. That is, the operation control portion 78e reads electrical information stored in the light receiving element, to generate the spectrum data of the reflected light. The spectrum data represents an intensity of the reflected light decomposed according to a wavelength, and changes depending on the film thickness.

The operation control portion 78e is connected to the above described control section 5. Thus, the spectrum data generated by the operation control portion 78e is transmitted to the control section 5. In the control section 5, a characteristic value associated with the film thickness of the wafer W is calculated based on the spectrum data received from the operation control portion 78e, and uses the characteristic value as a monitoring signal.

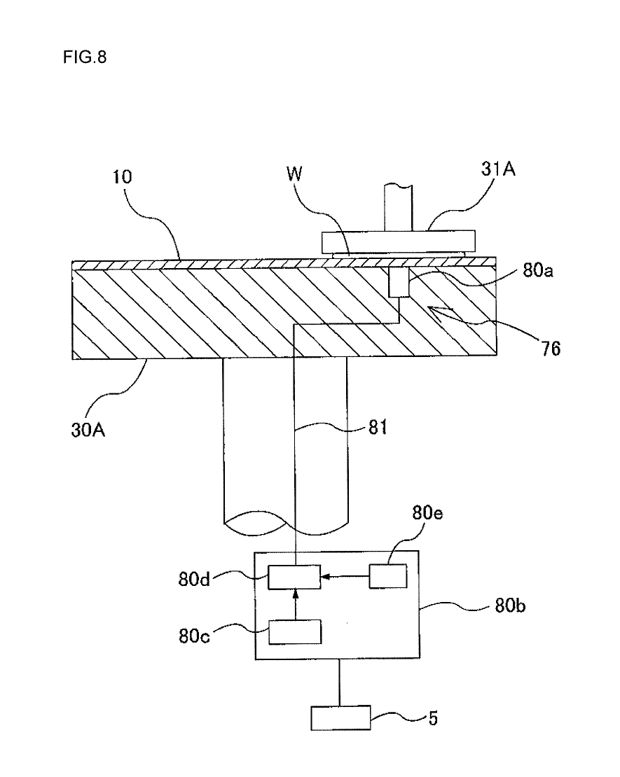

FIG. 8 is a schematic view illustrating a polishing table including a microwave sensor. A sensor 76 includes an antenna 80a that irradiates a polishing surface of a wafer W with a microwave, a sensor main body 80b that supplies the microwave to the antenna 80a, and a waveguide 81 that connects the antenna 80a and the sensor main body 80b. The antenna 80a is embedded in the polishing table 30A, and is arranged to oppose a position at the center of the wafer W retained in the top ring 31A.

The sensor main body 80b includes a microwave source 80c that generates a microwave and supplies the microwave to the antenna 80a, a separator 80d that separates the microwave (incident wave) generated by the microwave source 80c and a microwave (reflected wave) reflected from a surface of the waver W, and a detection portion 80e that receives the reflected wave obtained by the separation by the separator 80d and detects an amplitude and a phase of the reflected wave. A directional coupler is appropriately used as the separator 80d.

The antenna 80a is connected to the separator 80d via the waveguide 81. The microwave source 80c is connected to the separator 80d, and the microwave generated by the microwave source 80c is supplied to the antenna 80a via the separator 80d and the waveguide 81. The microwave is irradiated toward the waver W from the antenna 80a, to reach the wafer W after penetrating the polishing pad 10. The reflected wave from the wafer W is received by the antenna 80a again after penetrating the polishing pad 10.

The reflected wave is sent to the separator 80d from the antenna 80a via the waveguide 81. The separator 80d separates the incident wave and the reflected wave. The reflected wave obtained by the separation by the separator 80d is transmitted to the detection portion 80e. The detection portion 80e detects the amplitude and the phase of the reflected wave. The amplitude of the reflected wave is detected as power (dbm or W) or a voltage (V), and the phase of the reflected wave is detected by a phase measuring device (not illustrated) contained in the detection portion 80e. The amplitude and the phase of the reflected wave, which have been detected by the detection portion 80e, are sent to the control section 5. The film thickness of the metallic film or the nonmetallic film of the waver W is analyzed based on the amplitude and the phase of the reflected wave. The control section 5 monitors a value obtained by the analysis as a monitoring signal.

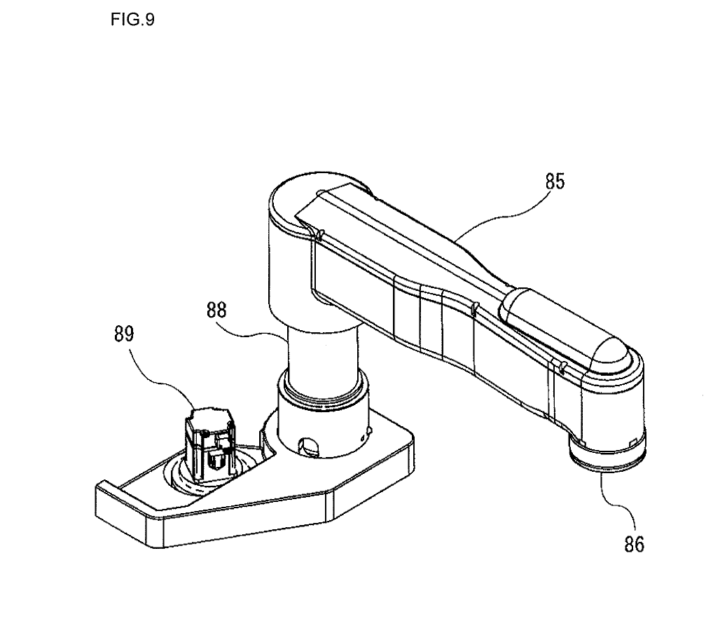

FIG. 9 is a perspective view illustrating the dresser 33A that can be used as an embodiment of the present invention. As illustrated in FIG. 9, the dresser 33A includes a dresser arm 85, a dressing member 86 rotatably attached to a leading end of the dresser arm 85, a swing shaft 88 connected to the other end of the dresser arm 85, and a motor 89 serving as a driving mechanism that swings the dresser arm 85 around the swing shaft 88. The dressing member 86 has a circular dressing surface, and hard particles are fixed to the dressing surface. The hard particles include diamond particles and ceramic particles. The dresser arm 85 contains a motor (not illustrated). The motor rotates the dressing member 86. The swing shaft 88 is connected to a lifting mechanism (not illustrated). This lifting mechanism lowers the dresser arm 85 so that the dressing member 86 presses the polishing surface of the polishing pad 10.

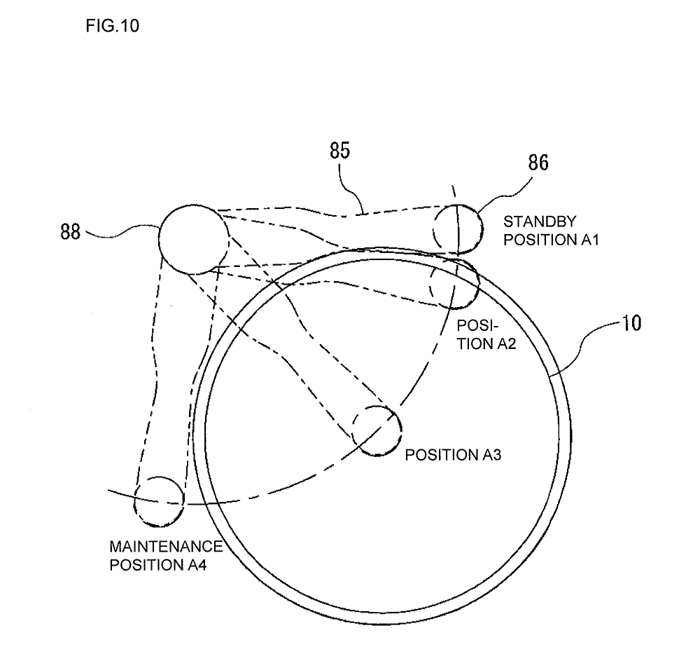

FIG. 10 is a plan view illustrating a movement locus when the dresser 33A dresses the polishing surface of the polishing pad 10. As illustrated in FIG. 10, the dresser arm 85 is longer than the radius of the polishing pad 10. The swing shaft 88 is positioned outside in a radial direction of the polishing pad 10. When the polishing surface of the polishing pad 10 is dressed, the polishing pad 10 is rotated while the motor rotates the dressing member 86, and the lifting mechanism then lowers the dresser arm 85, to slidably contact the polishing surface of the polishing pad 10 that rotates the dressing member 86. In the state, the motor 89 swings the dresser arm 85. While the polishing pad 10 is being dressed, pure water serving as a dressing liquid is supplied to the polishing surface of the polishing pad 10 from the polishing liquid supply nozzle 32A. By the swing of the dresser arm 85, the dressing member 86 positioned at its leading end can move to traverse the entire length of the polishing surface of the polishing pad 10 via the center of the polishing surface, as illustrated in FIG. 10. This swing operation enables the dressing member 86 to dress the polishing surface of the polishing pad 10 over the whole including the center thereof and enables a dressing effect to the polishing surface to be dramatically enhanced. Therefore, the entire polishing surface can be uniformly dressed so that a flat polishing surface is obtained.

After the end of the dressing, the dresser arm 85 moves to a standby position A1 beside the polishing table 30A, as illustrated in FIG. 10. During maintenance of the dresser 33A, the dresser arm 85 moves to a maintenance position A4 on the substantially opposite side of the standby position A1. As illustrated in FIG. 10, the dresser arm 85 may be swung between a position A2 at an end of the polishing surface and a position A3 at the center of the polishing surface during the dressing. Such an operation enables the dressing operation to be quickly performed and to be reliably ended.

In the above described example, the lifting mechanism connected to the swing shaft 88 integrally moves the dresser arm 85 and the dressing member 86 up and down. However, the lifting mechanism may be contained in the dresser arm 85, to move the dressing member 86 up and down. Further, in another modified example, a first lifting mechanism for moving the swing shaft 88 up and down can be provided while a second lifting mechanism for moving the dressing member 86 up and down can also be contained in the dresser arm 85. In this case, the first lifting mechanism can lower the dresser arm 85, and the second lifting mechanism can lower the dressing member 86 at the time point where the dresser arm 85 is at a predetermined height position. Such a configuration enables a pressing force against the polishing surface during the dressing and the height of the dressing member 86 to be accurately adjusted.

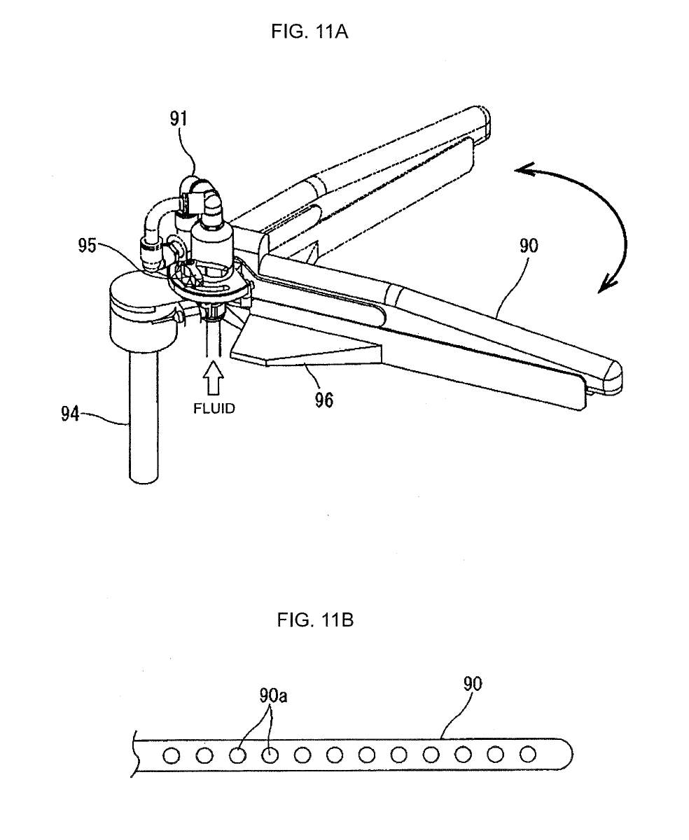

FIG. 11A is a perspective view illustrating the atomizer 34A. The atomizer 34A includes an arm 90 having one or a plurality of injection holes at its bottom, a fluid flow path 91 connected to the arm 90, and a swing shaft 94 that supports the arm 90. FIG. 11B is a schematic view illustrating the bottom of the arm 90. In an example illustrated in FIG. 11B, a plurality of injection holes 90a is equally spaced at the bottom of the arm 90. The fluid flow path 91 can include a tube or a pipe or a combination of the tube and the pipe.

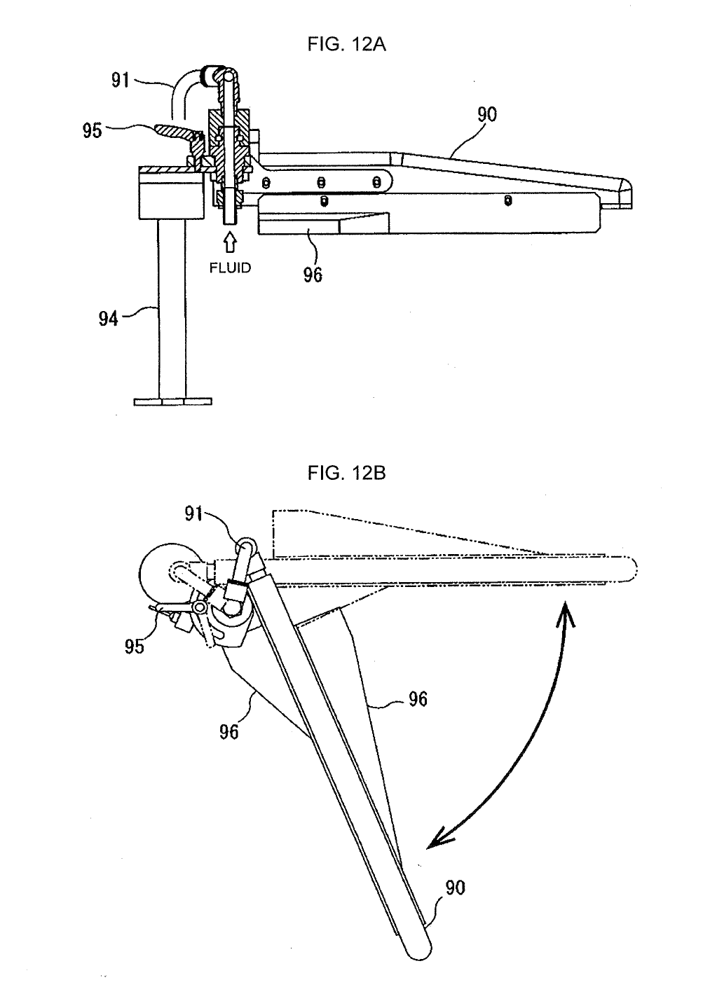

FIG. 12A is a side view illustrating an internal structure of the atomizer 34A, and FIG. 12B is a plan view illustrating the atomizer 34A. An opening end of a fluid flow path 91 is connected to a fluid supply pipe (not illustrated) so that a fluid is supplied to the fluid flow path 91 from the fluid supply pipe. An example of a fluid to be used includes a fluid (e.g., pure water) or a mixed fluid of a fluid and gas (e.g., a mixed fluid of pure water and nitrogen gas). The fluid flow path 91 communicates with the injection holes 90a in the arm 90, and the fluid is injected as a mist onto the polishing surface of the polishing pad 10 from the injection holes 90a.

The arm 90 can swirl between a cleaning position and a retreat position around a swing shaft 94, as indicated by respective dotted lines in FIGS. 11A and 12B. A movable angle of the arm 90 is approximately 90°. The arm 90 is normally at the cleaning position, and is arranged along the radius of the polishing surface of the polishing pad 10, as illustrated in FIG. 1. During maintenance such as replacement of the polishing pad 10, the arm 90 manually moves to the retreat position. Therefore, the arm 90 need not be detached during the maintenance so that a maintenance property can be improved. A rotation mechanism may be connected to the swing shaft 94, to swirl the arm 90.

As illustrated in FIG. 12B, two reinforcement members 96, which differ in shape, are provided on both side surfaces of the arm 90. The reinforcement members 96 are provided so that an atomizing operation can be effectively performed without an axis of the arm 90 significantly deviating when the arm 90 performs a swirling operation between the cleaning position and the retreat position. The atomizer 34A includes a lever 95 for fixing a swirl position of the arm 90 (an angular range in which the arm 90 can swirl). That is, an angle at which the arm 90 can swirl can be adjusted to match a condition by operating the lever 95. When the lever 95 is turned, the arm 90 can be freely swirled. The arm 90 is manually moved between the cleaning position and the retreat position. When the lever 95 is fastened, a position of the arm 90 is fixed at either one of the cleaning position and the retreat position.

The arm 90 in the atomizer 34A can also be made foldable. More specifically, the arm 90 may include at least two arm members connected to each other with a joint. In this case, an angle formed between the arm members when folded is not less than 1° nor more than 45°, and preferably not less than 5° nor more than 30°. When the angle formed between the arm members is more than 45°, a space occupied by the arm 90 increases. When the angle is less than 1°, the width of the arm 90 is forced to be decreased, resulting in a decreased mechanical strength. In this example, the arm 90 may be prevented from rotating around the swing shaft 94. During maintenance such as replacement of the polishing pad 10, the arm 90 is folded so that the atomizer 34A does not interfere with maintenance work. In another modified example, the arm 90 in the atomizer 34A can also be extensible and contractable. Also in this example, the arm 90 is contracted during maintenance so that the atomizer 34A does not interfere with maintenance work.

A purpose of providing the atomizer 34A is to rinse away a polishing sludge or an abrasive grain remaining on the polishing surface of the polishing pad 10 with a high-pressure fluid. More preferable dressing, i.e., reproduction of the polishing surface can be achieved by purification of the polishing surface by a fluid pressure of the atomizer 34A and dressing work of the polishing surface by the dresser 33A serving as mechanical contact. The polishing surface may generally, in many cases, be reproduced by the atomizer after being dressed by a contact dresser (e.g., a diamond dresser).

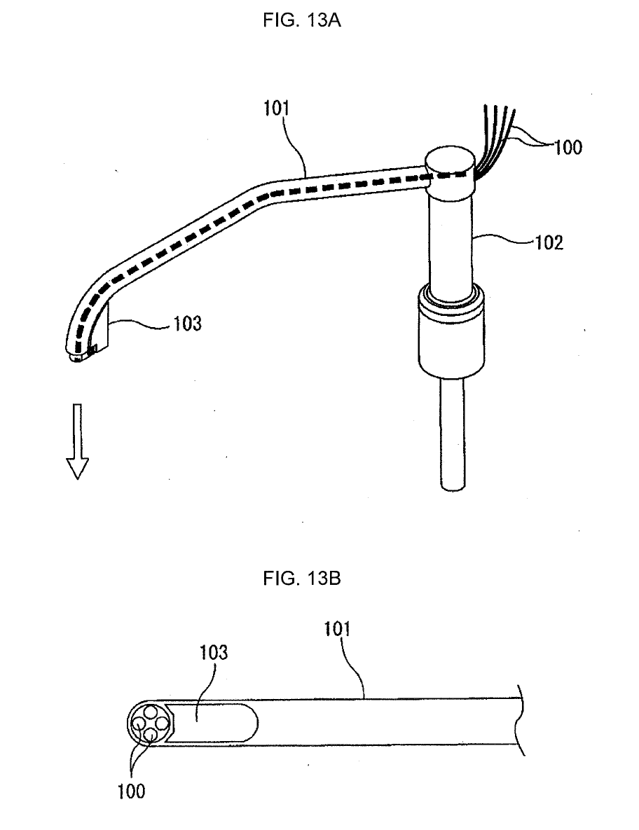

FIG. 13A is a perspective view illustrating the polishing liquid supply nozzle 32A, and FIG. 133 is an enlarged schematic view illustrating a leading end of the polishing liquid supply nozzle 32A as viewed from below. As illustrated in FIGS. 13A and 13B, the polishing liquid supply nozzle 32A includes a plurality of tubes 100 for supplying a polishing liquid such as pure water or a slurry to the polishing surface of the polishing pad 10, a pipe arm 101 that covers the plurality of tubes 100, and a swing shaft 102 that supports the pipe arm 101. The plurality of tubes 100 generally includes a pure water supply tube for supplying pure water and a plurality of slurry supply tubes for supplying different types of slurries. An example of the plurality of tubes 100 can include two or more and four or less (e.g., three) slurry supply tubes through which a slurry passes and one or two pure water supply tubes through which pure water passes.

The plurality of tubes 100 extends toward a leading end of the pipe arm 101 after passing through the pipe arm 101, and the pipe arm 101 covers the substantially whole tube 100. A reinforcement member 103 is fixed to the leading end of the pipe arm 101. A leading end of the tube 100 is positioned above the polishing pad 10 so that the polishing liquid is supplied onto the polishing surface of the polishing pad 10 from the tube 100. An arrow illustrated in FIG. 13A indicates the polishing liquid to be supplied to the polishing surface. The swing shaft 102 is connected to a rotation mechanism (e.g., a motor) (not illustrated), and the swing shaft 102 is rotated so that the polishing liquid can be supplied to a desired position on the polishing surface. During maintenance such as replacement of the polishing pad 10, the pipe arm 101 swings by a rotation mechanism around the swing shaft 102, and moves toward the retreat position beside the polishing table 30A.

As described above, the pipe arm 101 covers almost all of the plurality of tubes 100. Thus, a surface area of the entire nozzle 32A can be made smaller than when the pipe arm 101 does not cover the plurality of tubes 100. Therefore, an area to which some slurries, which has been blown up during polishing or processing using an atomizer, adhere decreases. As a result, an adverse effect on a polishing process due to the drop of the slurry, which has adhered, is prevented. Furthermore, the polishing liquid supply nozzle 32A becomes easy to clean.

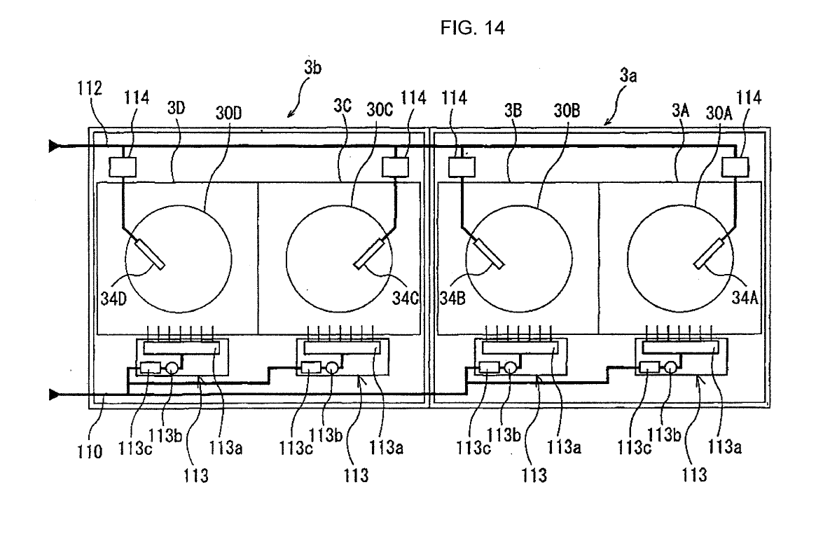

FIG. 14 is a schematic view illustrating pure water supply piping in the polishing section 3. In the substrate processing apparatus, the first polishing unit 3A and the second polishing unit 3B constitute a first polishing section 3a as one unit, the third polishing unit 3C and the fourth polishing unit 3D constitute a second polishing section 3b as one unit. The first polishing section 3a and the second polishing section 3b are separable from each other. As described above, the polishing section 3 uses various types of fluids such as pure water, air, and nitrogen gas. For example, pure water (DIW) is supplied to the pure water supply pipe 110 in the substrate processing apparatus from a pure water supply source (not illustrated), as illustrated in FIG. 14. The pure water supply pipe 110 extends through the polishing units 3A, 3B, 3C, and 3D in the polishing section 3, and is connected to distribution control portions 113 respectively provided in the polishing units 3A, 3B, 3C, and 3D.

The pure water supply pipe 110 is divided between the first polishing section 3a and the second polishing section 3b. A connection mechanism (not illustrated) connects respective ends of the divided pure water supply pipe 110. Applications of the pure water used in each of the polishing units 3A, 3B, 3C, and 3D include cleaning of a top ring (e.g., cleaning of an outer peripheral side surface of the top ring, cleaning of a substrate retaining surface, or cleaning of a retainer ring), cleaning of a conveyance hand of a wafer (e.g., cleaning of respective conveyance hands of first and second linear transporters, described below), cleaning of the polished wafer, dressing of a polishing pad, cleaning of a dresser (e.g., cleaning of a dressing member), cleaning of a dresser arm, cleaning of a polishing liquid supply nozzle, and cleaning of a polishing pad using an atomizer.

The pure water flows into each of the distribution control portions 113 via the pure water supply pipe 110, and is distributed among points of use, respectively, by the distribution control portions 113. The point of use is a point where pure water is used, e.g., the nozzle for top ring cleaning or the nozzle for dresser cleaning, described above. The pure water is supplied to terminal equipment such as a cleaning nozzle (e.g., the nozzle for top ring cleaning or the nozzle for dresser cleaning, described above) provided in each of the polishing units 3A, 3B, 3C, and 3D from the distribution control portion 113. Pure water with a flow rate adjusted by the distribution control portion 113 for each of the polishing units 3A, 3B, 3C, and 3D is supplied to the pure water supply tubes 100 in the above described polishing liquid supply nozzle 32A (see FIG. 13A), for example. Thus, the distribution control portion 113 is arranged for each of the polishing units 3A, 3B, 3C, and 3D. Thus, the number of pipes can be made smaller than that in a conventional structure in which pure water is supplied to polishing units via a plurality of pipes from one header. This means that the number of connection mechanisms, which connect the pipes between the first polishing section 3a and the second polishing section 3b, is reduced. Thus, a structure becomes simple while a risk of leakage of pure water is reduced. The atomizer requires a large amount of pure water. Thus, a pure water supply pipe 112 dedicated to the atomizer is preferably provided, as illustrated in FIG. 14.

Each of the distribution control portions 113 includes a valve box 113a communicating with the point of use such as the nozzle for top ring cleaning (not illustrated) and the pure water supply tube 100 (see FIG. 13A), a pressure gauge 113b provided upstream of the valve box 113a, and a flow regulator 113c provided upstream of the pressure gauge 113b. The valve box 113a includes a plurality of pipes respectively communicating with the points of use and valves respectively provided in the pipes.

The pressure gauge 113b measures pressure of pure water to be fed to the valve box 113a, and the flow regulator 113c regulates a flow rate of the pure water so that a measured value of the pressure gauge 113b is maintained at a predetermined value. Thus, the flow rate of the pure water is controlled by each of the polishing units 3A, 3B, 3C, and 3D. Thus, the effect of the use of the pure water between the polishing units is reduced so that the pure water can be stably supplied. Therefore, a problem in the conventional structure in which the flow rate of the pure water in the certain polishing unit becomes unstable due to the effect of the use of the pure water in the other polishing unit. In an example illustrated in FIG. 14, the polishing units 3A, 3B, 3C, and 3D are respectively provided with flow regulators 113c. However, one flow regulator 113c may be arranged for two polishing units. For example, one set of the pressure gauge 113b and the flow regulator 113c may be provided upstream of the two valve boxes 113a respectively provided in the polishing units 3A and 3B, and one set of the pressure gauge 113b and the flow regulator 113c may similarly be provided upstream of the two valve boxes 113a respectively provided in the polishing units 3C and 3D.

In the example illustrated in FIG. 14, a pure water supply pipe 112 dedicated to the atomizers 34A, 34B, 34C, and 34D is provided separately from the pure water supply pipe 110 for the points of use such as the nozzle for top ring cleaning (not illustrated) and the pure water supply tube 100. The pure water supply pipe 112 is connected to the atomizers 34A, 34B, 34C, and 34D, and flow control portions 114 are respectively provided upstream of the atomizers 34A, 34B, 34C, and 34D. The flow control portion 114 adjusts a flow rate of pure water supplied from the pure water supply pipe 112 and feeds the respective pure water with the adjusted flow rate to the atomizers 34A, 34B, 34C, and 34D.

Each of the flow control portions 114 includes a valve, a pressure gauge, and a flow regulator, similarly to the above described distribution control portion 113, and their arrangement is similar to the arrangement in the distribution control portion 113. The control section 5 controls an operation of the flow regulator in the flow control portion 114 so that pure water with a predetermined flow rate is supplied to each of the atomizers 34A, 34B, 34C, and 34D based on a measured value of the pressure gauge in the flow control portion 114.

As illustrated in FIG. 14, the pure water supply pipe 110 and the pure water supply pipe 112 are respectively independently connected to a pure water supply source, and different pure water supply paths are ensured. Such an arrangement can prevent the use of the pure water in the atomizer from affecting the flow rate of the pure water at the other point of use.

FIG. 14 illustrates the pure water supply pipe 110 that supplies the pure water. However, an arrangement of piping and the distribution control portions 113 illustrated in FIG. 14 is also applicable to a supply pipe of another fluid such as air, nitrogen gas, or a slurry. For example, a plurality of slurry supply pipes, which transfers a plurality of types of slurries, can be provided, and distribution control portions 113 connected to the slurry supply pipes can be respectively provided for the polishing units 3A, 3B, 3C, and 3D. Each of the distribution control portions 113 supplies the slurry, which has been selected depending on the polishing processing, to the above described polishing liquid supply nozzle (FIG. 13A). The distribution control portion 113 is provided for each of the polishing units 3A, 3B, 3C, and 3D. Thus, the type of the slurry to be supplied to the polishing liquid supply nozzle can be changed for each of the polishing units 3A, 3B, 3C, and 3D. Further, the distribution control portion 113 adjusts a flow rate of the slurry to be supplied to the polishing liquid supply nozzle 32A.

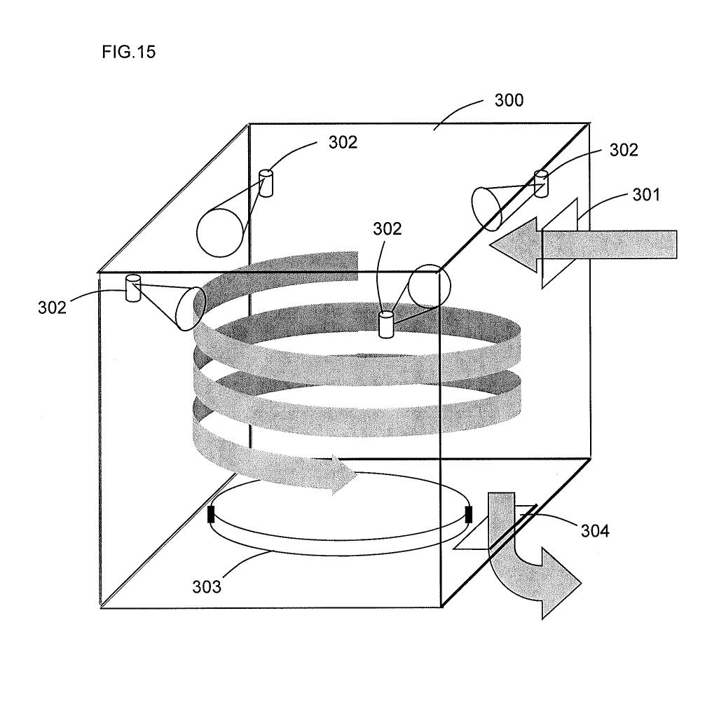

A characteristic configuration of the substrate polishing apparatus according to the embodiment of the present invention will be described below with reference to FIGS. 15 to 24. FIG. 15 illustrates the substrate polishing apparatus according to the present embodiment. As illustrated in FIG. 15, in the present embodiment, a gas supply port 301, which supplies gas into a polishing chamber 300, is provided in an upper part of the polishing chamber 300. The gas includes air. A spray nozzle 302, which sprays a cleaning liquid in a mist into the polishing chamber 300, is provided on an inner wall surface of the polishing chamber 300. A polishing portion (polishing table) 303, which polishes a substrate, and a gas discharge port 304, which discharges gas from inside the polishing chamber 300, are provided in a lower part of the polishing chamber 300. In this case, the gas discharge port 304 is provided in the vicinity of the polishing portion 303.

As illustrated in FIG. 15, the gas supply port 301 is arranged at a position offset sideward from the center of the inner wall surface of the polishing chamber 300. The gas supply port 301 is thus offset so that the gas (air) supplied from the gas supply port 301 swirls in the polishing chamber 300.

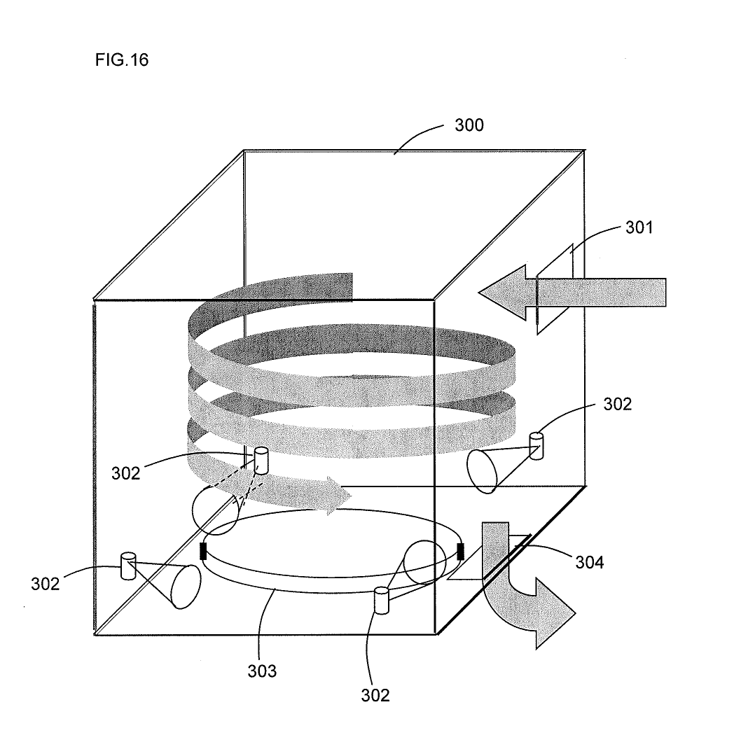

A plurality of spray nozzles 302 can be provided. In an example illustrated in FIG. 15, four spray nozzles 302 are provided in an upper part of the polishing chamber 300. For example, one of the spray nozzles 302 is arranged in the vicinity of the gas supply port 301. The spray nozzle 302 can also be provided in a lower part of the polishing chamber 300. In an example illustrated in FIG. 16, four spray nozzles 302 are provided in a lower part of the polishing chamber 300. For example, one of the spray nozzles 302 is arranged in the vicinity of the gas discharge port 304.

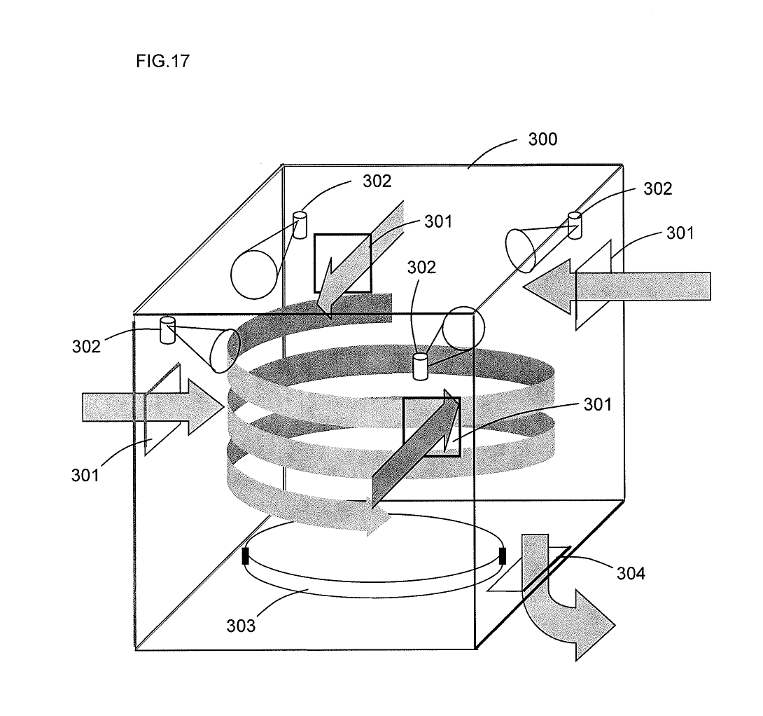

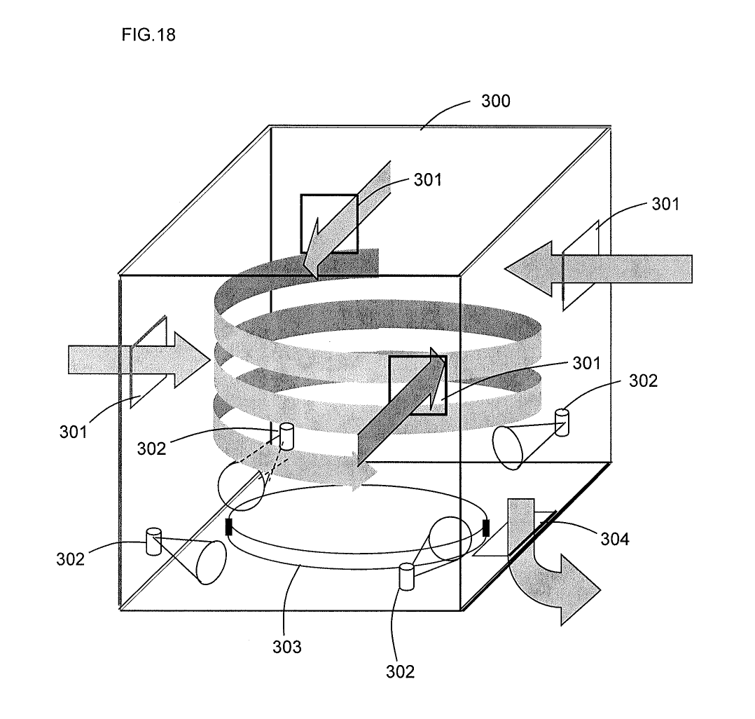

While one gas supply port 301 is provided in the polishing chamber 300 in the examples illustrated in FIGS. 15 and 16, a plurality of gas supply ports 301 may be provided in the polishing chamber 300, as illustrated in FIGS. 17 and 18. In FIGS. 17 and 18, for example, four gas supply ports 301 are respectively provided at different positions in a lower part of the polishing chamber 300.

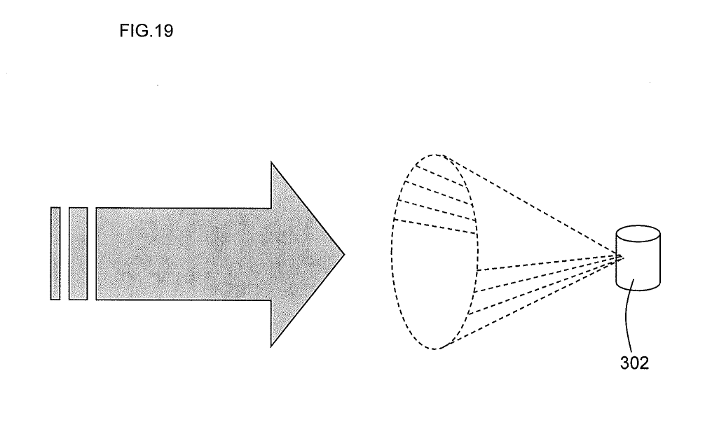

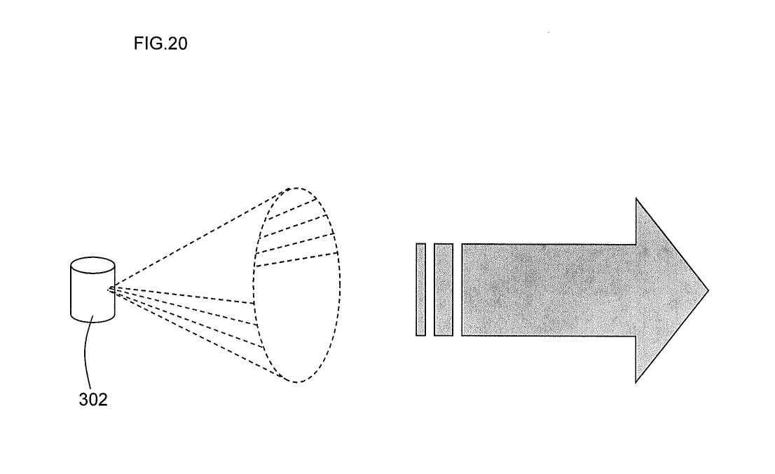

As illustrated in FIGS. 15 to 18, a direction of the spray nozzle 302 is set so that a cleaning liquid is sprayed toward a space at the center of the polishing chamber 300 from the inner wall surface thereof. In this case, the direction of the spray nozzle 302 can be set to a direction opposite to the flow of gas supplied from the gas supply port 301 (see FIG. 19). The direction of the spray nozzle 302 may be set to the same direction as the flow of gas supplied from the gas supply port 301 (see FIG. 20).

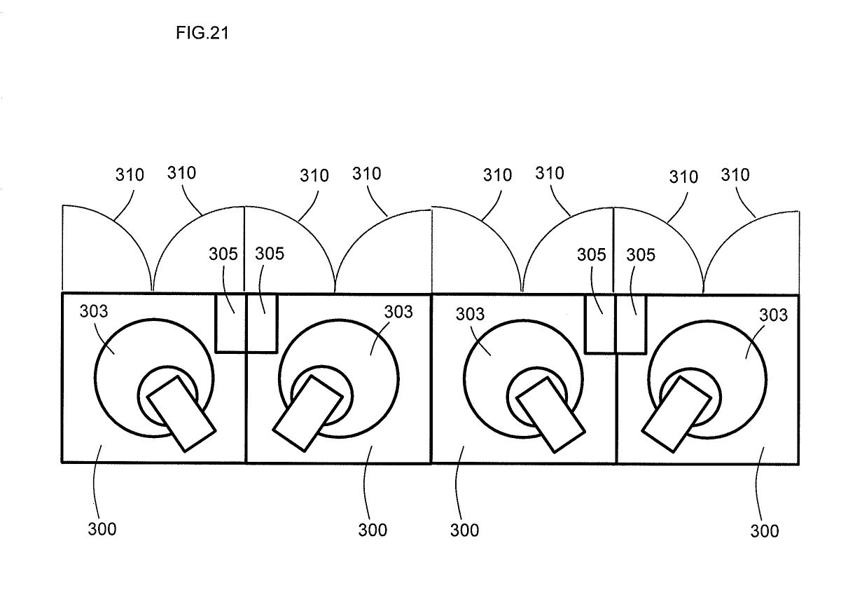

FIG. 21 corresponds to the polishing section 3 illustrated in FIG. 1. The upper side of FIG. 21 corresponds to the left side of FIG. 1. Maintenance doors 310, which are openable and closable, are provided on the upper side of FIG. 21. The polishing section 3 can be maintained from outside the polishing apparatus by opening the maintenance door 310. An opening of a sealed glove is provided on a side surface on the side of the maintenance door 310 of the polishing apparatus. The opening of the sealed glove may be provided on the maintenance door 310, or may be provided on a wall surface, which is not the maintenance door 310, serving as the side surface of the polishing apparatus.

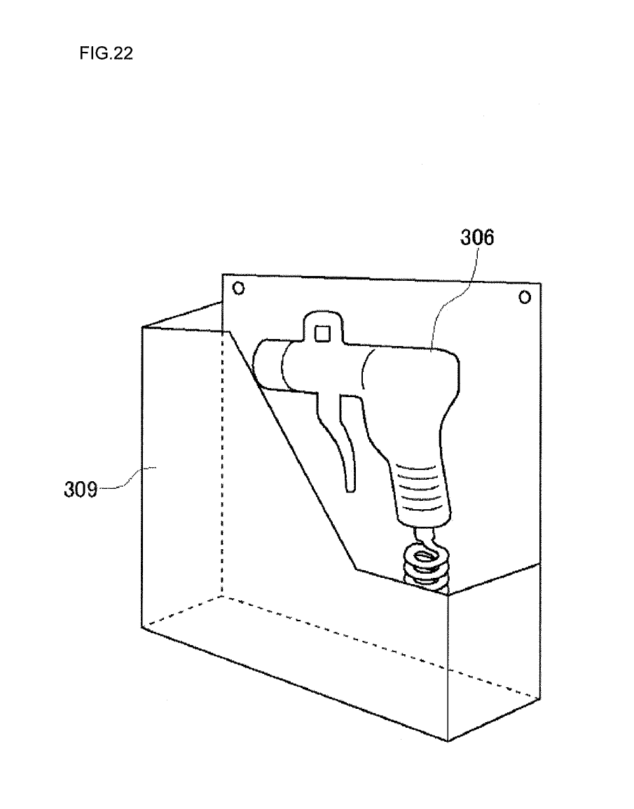

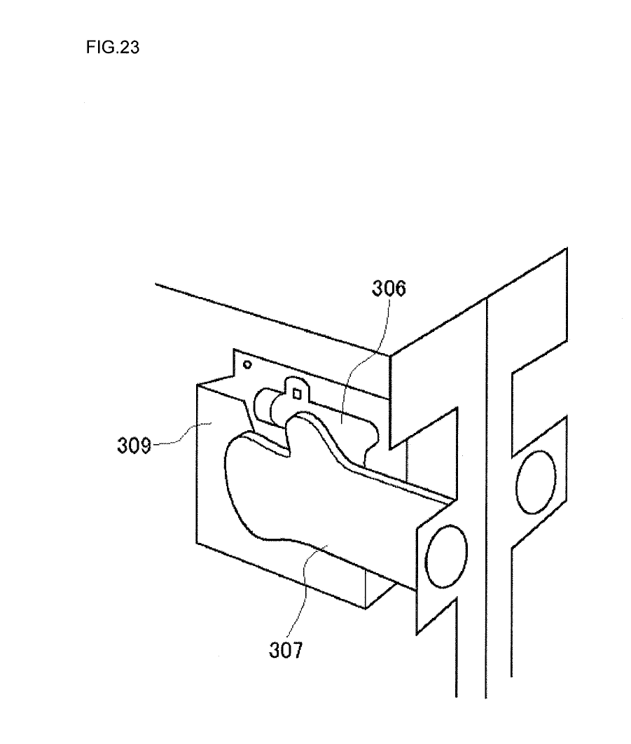

As illustrated in FIG. 21, a glove box 305 is provided in the polishing chamber 300. The glove box 305 includes a hand-held cleaning tool 306 for cleaning the inside of the polishing chamber 300 and a sealed glove 307 for operating the hand-held cleaning tool 306 from outside the polishing chamber 300 (see FIGS. 22 and 23).

The sealed glove 307 is manufactured using a material into which a chemical liquid used for cleaning does not penetrate. The opening of the sealed glove 307 is opened toward the outside of the polishing chamber 300 so that a worker can put his/her hand in the sealed glove 307. The inside of the sealed glove 307 is isolated from an atmosphere inside the polishing chamber 300. During cleaning, the worker puts his/her hand in the sealed glove 307 from the opening thereof, and cleans the inside of the polishing chamber 300 using the hand-held cleaning tool 306.

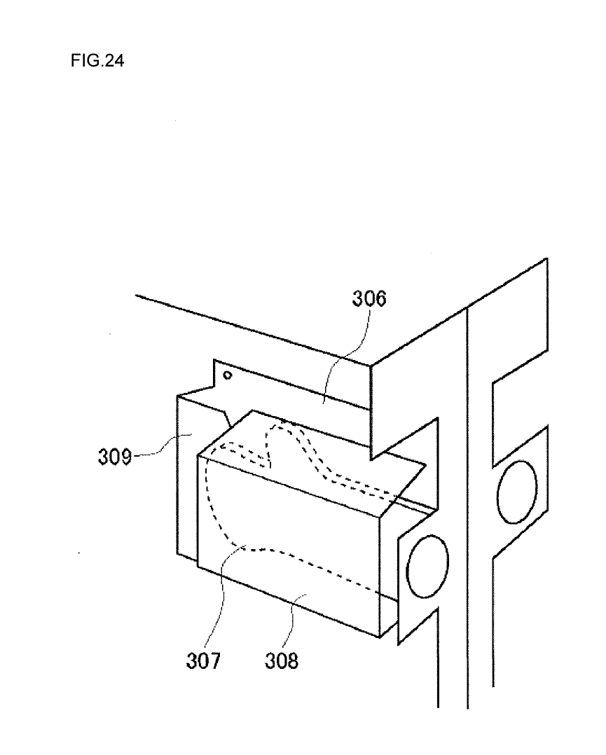

The glove box 305 includes a fixing member 308 for fixing the sealed glove 307 to the inner wall surface of the polishing chamber 300 (see FIG. 24). The fixing member 308 can perform a fixing/unfixing operation from outside the polishing chamber 300. The hand-held cleaning tool 306 is also housed in a housing portion 309 on the inner wall surface of the polishing chamber 300 during non-use (see FIG. 22).

In the substrate polishing apparatus according to the present embodiment, when gas is supplied from the gas supply port 301 at an offset position on the inner wall surface of the polishing chamber 300, the gas swirls in the polishing chamber 300. When the cleaning liquid is sprayed from the spray nozzle 302 toward a space at the center of the polishing chamber 300, the mist of cleaning liquid swirls in the gas in the polishing chamber 300. Even if a harmful substance (powder or gas) is generated in the polishing chamber 300 during polishing of the substrate, therefore, the harmful substance can be trapped with the cleaning liquid. The harmful substance trapped with the cleaning liquid, together with the gas, is discharged from the gas discharge port 304. Thus, the harmful substance suspended in the polishing chamber 300 can be effectively trapped and safely discharged.

In the present embodiment, the one or more gas supply ports 301 are respectively provided at different positions in an upper part of the polishing chamber 300. Therefore, the gas is supplied from the plurality of gas supply ports 301 provided at the different positions in an upper part of the polishing chamber 300 so that the gas can easily swirl in the polishing chamber 300.

In the present embodiment, the gas supply port 301 is provided in an upper part of the polishing chamber 300, and the spray nozzle 302 is arranged in the vicinity of gas supply port 301. Therefore, as soon as the gas is supplied from the gas supply port 301 in an upper part of the polishing chamber 300, the cleaning liquid can be put on the gas, and the harmful substance in the polishing chamber 300 can be trapped form an early stage.

Alternatively, the gas discharge port 304 is provided in the vicinity of the polishing portion 303 in a lower part of the polishing chamber 300, and the spray nozzle 302 is arranged in the vicinity of the gas discharge port 304. If the harmful substance (powder or gas) is generated during polishing of the substrate in a lower part of the polishing chamber 300, therefore, the harmful substance can be trapped close to a place where the harmful substance has been generated (as soon as the harmful substance has been generated).

In the present embodiment, the direction of the spray nozzle 302 is set to a direction opposite to the flow of the gas supplied from the gas supply port 301. When the harmful substance flows on the gas in the polishing chamber 300, the cleaning liquid is sprayed toward the gas (harmful substance). Thus, the harmful substance, which has flowed on the gas, can be effectively trapped with the cleaning liquid.

Alternatively, the direction of the spray nozzle 302 is set to the same direction as the flow of the gas supplied from the gas supply port 301. Therefore, the cleaning liquid is sprayed in the same direction as the gas flowing in the polishing chamber 300. Thus, the harmful substance in a wide range of the polishing chamber 300 can be effectively trapped with the cleaning liquid put on the gas flowing in the polishing chamber 300.

In the present embodiment, the substrate polishing apparatus includes the hand-held cleaning tool 306 for cleaning the inside of the polishing chamber 300 and the sealed glove 307 for operating the hand-held cleaning tool 306 from outside the polishing chamber 300. If the harmful substance is insufficiently removed only by being trapped with the cleaning liquid, therefore, the harmful substance remaining in the polishing chamber 300 can be cleaned by operating the hand-held cleaning tool 306 via the sealed glove 307.

In this case, the substrate polishing apparatus includes a fixing member 308 for fixing the sealed glove 307 on the inner wall surface of the polishing chamber 300. When the sealed glove 307 is unused, therefore, the sealed glove 307 can be fixed to the inner wall surface of the polishing chamber 300 using the fixing member 308, and can be prevented from contacting another structure in the polishing chamber 300.

While the embodiment of the present invention has been described with examples, the scope of the present invention is not limited to these, and can be modified and varied depending on purposes within the scope described in the claims.

As described above, the substrate polishing apparatus according to the present invention has the effect of effectively trapping the harmful substance suspended in the polishing chamber, and is usefully applied to the substrate processing apparatus.

1. A substrate polishing apparatus comprising:
a polishing portion that polishes a substrate in a polishing chamber;
a gas supply port that supplies gas to the polishing chamber;
a gas discharge port that discharges the gas from inside the polishing chamber; and
a spray nozzle that is provided on an inner wall surface of the polishing chamber and sprays a cleaning liquid in a mist into the polishing chamber,
wherein the gas supply port is arranged to generate a swirl flow.

2. The substrate polishing apparatus according to claim 1, wherein
the gas supply port is arranged at a position offset sideward from the center of the inner wall surface of the polishing chamber, and
a direction of the spray nozzle is set to spray the cleaning liquid toward a space at the center of the polishing chamber from the inner wall surface thereof.

3. The substrate polishing apparatus according to claim 2, wherein a plurality of the gas supply ports are each provided at different positions in an upper part of the polishing chamber.

4. The substrate polishing apparatus according to claim 2, wherein
the gas supply port is provided in an upper part of the polishing chamber, and
the spray nozzle is arranged in the vicinity of the gas supply port.

5. The substrate polishing apparatus according to claim 2, wherein
the gas discharge port is provided in the vicinity of the polishing portion in a lower part of the polishing chamber, and
the spray nozzle is arranged in the vicinity of the gas discharge port.

6. The substrate polishing apparatus according to claim 1, wherein the direction of the spray nozzle is set in a direction opposite to the flow of the gas supplied from the gas supply port.

7. The substrate polishing apparatus according to claim 1, wherein the direction of the spray nozzle is set in the same direction as that of the flow of the gas supplied from the gas supply port.

8. The substrate polishing apparatus according to claim 1, further comprising
a hand-held cleaning tool for cleaning the inside of the polishing chamber, and
a sealed glove for operating the hand-held cleaning tool from outside the polishing chamber.

9. The substrate polishing apparatus according to claim 8, further comprising a fixing member for fixing the sealed glove to the inner wall surface of the polishing chamber.
